(19) United States
(12) Patent Application Publication
(10) Pub. No.: US 2008/0247124 A1
(43) Pub. Date: Oct. 9, 2008

(54) APPARATUS FOR PROTECTING POWER SWITCH

(76) Inventors: Ming-Chun Lai, Tu-Cheng City (TW); Yan Hu, Tu-Cheng City (TW)

Correspondence Address: BIRCH STEWART KOLASCH & BIRCH, PO BOX 747, FALLS CHURCH, VA, 22040-0747, US

(21) Appl. No.: 11/697,256

(22) Filed: Apr. 5, 2007

(51) Int. Cl. H05K 7/14

(52) U.S. Cl. 361/679

(57) ABSTRACT

An apparatus for protecting power switch includes a protecting board attached to a casing plate to cover the power switch. The edges of the protecting board bend vertically to form soldering portions to locate the protecting board on the casing plate, and then a groove is formed between the protecting board and the casing plate. One end of the groove is sealed and the other end of the groove is open, forming an inserting mouth sealed by a stopping section. The protecting board further defines an opening for exposing the power switch. A protecting gate is set in the groove and can slide along the groove to protect the power switch exposed.

### BACKGROUND OF THE INVENTION

1. Field of the Invention

The present invention relates to an apparatus for protecting power switch of a computer and the like.

2. The Related Art

As well known that a computer includes a host and a monitor. The host has a case to protect the host thereof. A front casing plate of the case usually includes many interfaces such as a CD-ROM, a FD, a USB interface and an earphone interface as well as a power switch. The monitor is placed on a desk and the host is placed under the desk beside a user. Then in the process of using the computer, the user's shoe is easy to hit against the power switch of the computer. It leads the power of the computer cut off unintentionally and causes the computer to be turned off abnormally. So the user's data that are being dealt with can't be protected in time and the computer is destroyed easily. In a word, it brings much trouble to the user.

In order to solve the above problem, an electric powered gate to protect the power switch is developed. The electric powered gate has a protecting gate mounted in the front of the casing plate, a control panel connecting with the protecting gate, an electromotor mechanism installed in the back of the casing plate. The electromotor mechanism contains an electromotor, a conveyer belt, a swinging wheel and a swinging shaft. The electromotor connects with the swinging wheel via the conveyer belt and the swinging wheel further links one end of the swinging shaft. The other end of the swinging shaft connects with the control panel. The electromotor drives the swinging wheel swing and further drives the swinging shaft swing. Correspondingly the swinging shaft brings the control panel remove and further brings the protecting gate remove up and down along the casing plate. Then the computer is protected while the protecting gate removes down to cover the power switch of the computer.

However the structure of the electric powered gate described above is very complex and takes up a lot of space. It is not adaptable to current exquisite electric products. Moreover, the manufacture cost of the electric powered gate is too high. Therefore, it has become increasingly desirable to invent a simpler apparatus for protecting the power switch of the computer.

### SUMMARY OF THE INVENTION

Accordingly, an object of the present invention is to provide an apparatus for protecting power switch. The apparatus includes a protecting board attached to a casing plate to cover the power switch. The edges of the protecting board bend vertically to form soldering portions to locate the protecting board on the casing plate, and then a groove is formed between the protecting board and the casing plate. One end of the groove is sealed and the other end of the groove is open, forming an inserting mouth sealed by a stopping section. The protecting board defines an opening for exposing the power switch. A protecting gate is set in the groove and can slide along the groove to protect the power switch exposed.

As described above, because of the apparatus which is used to protect the power switch, the computer is used safely and also conveniently. Furthermore, the structure of the apparatus is very simple and takes up small space. Then the cost to make such apparatus is reduced.

### BRIEF DESCRIPTION OF THE DRAWINGS

The present invention will be apparent to those skilled in the art by reading the following description of a preferred embodiment thereof, with reference to the attached drawings, in which:

FIG. 1 is a perspective view of an apparatus for protecting power switch of the present invention assembled in a host of a computer;

FIG. 2 is a plan view of the apparatus which is in nature state;

FIG. 3 is a plan view of FIG. 2 when a protecting gate of the apparatus is pushed aside with a power switch exposed;

FIG. 4 is another perspective view of the apparatus for protecting power switch of the present invention assembled in the host of the computer;

FIG. 5 is a plan view of the apparatus of FIG. 4 which is in nature state; and

FIG. 6 is a plan view of FIG. 5 when the protecting gate of the apparatus is pushed upwards with the power switch exposed.

### DETAILED DESCRIPTION OF THE PREFERRED EMBODIMENTS

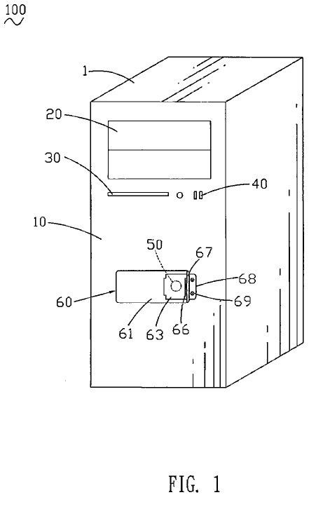

FIGS. 1-3 show a first embodiment of an apparatus 60 for protecting power switch of the present invention assembled in a host 100 of a computer. The host 100 includes a case 1 to protect the host 100 thereof. A front casing plate 10 of the case 1 includes a CD-ROM 20, a FD 30, a USB interface 40 and a power switch 50. The apparatus 60 is assembled transversely before the power switch 50.

The apparatus 60 has a protecting board 61 which is mounted on the front casing plate 10. The upper and low edge as well as the left edge of the protecting board 61 bends vertically to form three soldering portions to locate the protecting board 61 on the front casing plate 10. Then a groove 64 is formed transversely between the protecting board 61 and the front casing plate 10. The left side of the groove 64 is scaled and the right side of the groove 64 is open, forming an inserting mouth (not shown). The protecting board 61 defines an opening 62 with the power switch 50 exposed therethrough. The opening 62 defines a resisting portion 621 at the left edge thereof. A board-shaped protecting gate 63 is assembled in the groove 64. The right edge of the protecting gate 63 protrudes outward and defines a handle 66. One side of the handle 66 is hollow so as to remove the protecting gate 63 along the groove 64 easily. A spring 65 is received in the groove 64. One end of the spring 65 resists the left side of the groove 64 and the other end of the spring 65 resists the left wall of the protecting gate 63. A stopping section 67 seals the inserting mouth. The right side of the stopping section 67 connects with a linking section 68. Two screws 69 fix the linking section 68 on the front casing plate 10 and further fix the stopping section 67 on the casing plate 10.

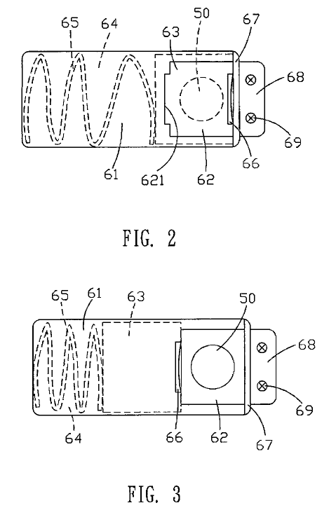

Referring to FIG. 2, in nature state, the spring 65 spreads to both sides and drives the protecting gate 63 to cover the power switch 50. The right wall of the protecting gate 63 is prevented from sliding out fully by the stopping section 67. Then it avoids the power switch 50 being touched and further avoids the computer being closed abnormally.

Referring to FIG. 3, When the computer needs to open or close, the protecting gate 63 is removed to the left side via the handle 66 till the handle 66 is blocked by the resisting portion 621. Then the power switch 50 is displayed. Push the power switch 50 can open or close the computer. At the time, the spring 65 is compressed. After the computer being opened or closed, the spring 65 stretches to both sides and brings the protecting gate 63 removing to cover the power switch 50. The protecting gate 63 is prevented from sliding out by the stopping section 67. Thereby, the power switch 50 is hidden behind the protecting gate 63 again.

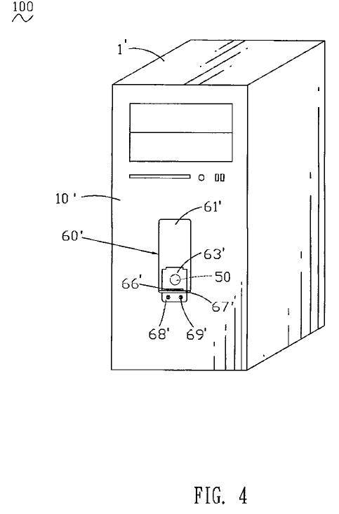

FIGS. 4-6 show a second embodiment of the apparatus 60′ for protecting power switch of the present invention assembled in the front casing plate 10′ of the case 1′ which belongs to the host 100 of the computer. The apparatus 60′ is set lengthways in the front of the power switch 50. The apparatus 60′ has a protecting board 61′ which is mounted on the front casing plate 10′. The left and right edge as well as the upper edge of the protecting board 61′ bends vertically to form three soldering portions to locate the protecting board 61′ on the front casing plate 10′. Then a groove 64′ is formed lengthways between the protecting board 61′ and the front casing plate 10′. The upper end of the groove 64′ is sealed and the lower end of the groove 64′ is open, forming an inserting mouth (not shown). The protecting board 61′ defines an opening 62′ with the power switch 50 exposed therethrough. The opening 62′ defines a resisting portion 621′ at the upper edge. A board-shaped protecting gate 63′ is assembled in the groove 64′. The protecting gate 63′ protrudes outward and defines a handle 66′ at the lower portion thereof. One side of the handle 66′ is hollow so as to remove the protecting gate 63′ along the groove 64′ easily. A stopping section 67′ seals the inserting mouth. The lower side of the stopping section 67′ connects with a linking section 48′. Two screws 49′ fix the linking section 48′ on the front casing plate 10′ and further fix the stopping section 67′ on the casing plate 10′.

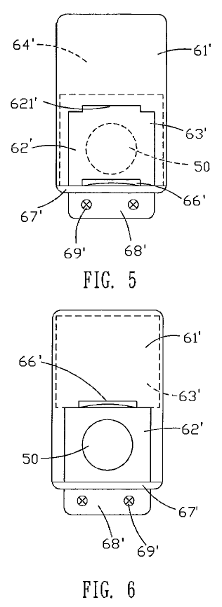

Referring to FIG. 5, in nature state, the protecting gate 63′ covers the power switch 50 in the action of the gravity force of the protecting gate 63′ itself. The protecting gate 63′ is prevented from sliding out fully by the stopping section 67′. Then it avoids the power switch 50 being touched and further avoids the computer being closed abnormally.

As shown in FIG. 6, When the computer needs to open or close, the protecting gate 63′ is pushed to the upper side via the handle 66′ till the handle 66′ is blocked by the resisting portion 621′. Then the power switch 50 is displayed. Push the power switch 50 can open or close the computer. After the computer being opened or closed, the protecting gate 63′ removes to cover the power switch 50 again in the action of the gravity force of the protecting gate 63′ itself. The protecting gate 63′ is prevented from sliding out by the stopping section 67′. Thereby, the power switch 50 is hidden behind the protecting gate 63′ again.

As described above, because of the apparatus which is used to protect the power switch 50, the computer is used safely and also conveniently. Furthermore, the structure of the apparatus for protecting power switch is very simple and takes up small space. Then the cost to make such apparatus is reduced.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. An apparatus for protecting power switch, comprising:
a protecting board attached to a casing plate to cover the power switch;
a groove formed between the protecting board and the casing plate, the edges of the protecting board bending vertically to form soldering portions to locate the protecting board on the casing plate, and then the groove being formed between the protecting board and the casing plate, one end of the groove sealed and the other end of the groove being open, forming an inserting mouth sealed by a stopping section;
an opening defined in the protecting board for exposing the power switch; and
a protecting gate set in the groove, the protecting gate sliding along the groove to protect the power switch exposed.

2. The apparatus for protecting power switch as claimed in claim 1, wherein the opening defines a resisting portion at one edge.

3. The apparatus for protecting power switch as claimed in claim 1, further comprising a spring, the spring received in the groove, one end of the spring against the groove and the other end of the spring against the protecting gate.

4. The apparatus for protecting power switch as claimed in claim 1, wherein the stopping section connects with a linking section located on the casing plate via screws.

5. The apparatus for protecting power switch as claimed in claim 2, wherein the protecting gate protrudes outward and defines a handle.

6. The apparatus for protecting power switch as claimed in claim 5, wherein one side of the handle is a cambered surface.

7. The apparatus for protecting power switch as claimed in claim 1, wherein the protecting board and the casing plate are formed together.
